(19) United States
(12) Patent Application Publication
(10) Pub. No.: US 2006/0108641 A1
(43) Pub. Date: May 25, 2006

(54) Device having a laterally graded well structure and a method for its manufacture

(75) Inventors: Yu-Chang Jong, Hsinchu City (TW); Chen-Bau Wu, Zhubei City (TW); Ruey-Hsing Liu, Hsin-Chu (TW); Kuo-Ming Wu, Hsin-Chu (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 10/992,861

(22) Filed: Nov. 19, 2004

(51) Int. Cl. H01L 29/76

(52) U.S. Cl. 257/371

(57) ABSTRACT

Provided are a device and method for its manufacture. In one example, the device includes a semiconductor substrate that includes a well region formed using a first-type dopant. First and second doped regions are formed in the well region using a second-type dopant, and the first and second doped regions are separated from each other by a dielectric isolation feature. A third doped region is formed in the well region using the first-type dopant and positioned under the dielectric isolation feature and between the first doped region and the second doped region. The third doped region has a dopant concentration higher than that of the well region.

### BACKGROUND

As metal-oxide-semiconductor field effect transistors (MOSFETs) are adapted for high voltage applications, light doped wells (also referred to as high voltage wells) may be used for higher breakdown voltages used in high voltage applications, such as in double diffused metal-oxide-semiconductor (DMOS) transistors.

However, light doped wells may lead to lower field device threshold voltages. For example, the field implantation commonly used to improve field isolation may not be suitable for high voltage wells because of breakdown concerns.

Accordingly, what is needed in the art is a semiconductor device and method of manufacturing thereof that addresses the above-discussed issues.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1A is a sectional view of one embodiment of a laterally graded well structure.

FIG. 1B is a plan view of one embodiment of the laterally graded well structure of FIG. 1A.

FIG. 2 is a flow chart of one embodiment of a method to fabricate a laterally graded well structure.

FIGS. 3A to 4F are sectional views of one embodiment of a laterally graded well isolation structure at intermediate fabrication stages.

FIG. 4A is a sectional view of another embodiment of a laterally graded well structure.

FIG. 4B is a plan view of one embodiment of the laterally graded well structure of FIG. 4A.

### DETAILED DESCRIPTION

The present disclosure relates generally to the field of semiconductor integrated circuits and, more particularly, to high voltage integrated circuits.

It is to be understood that the following disclosure provides many different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

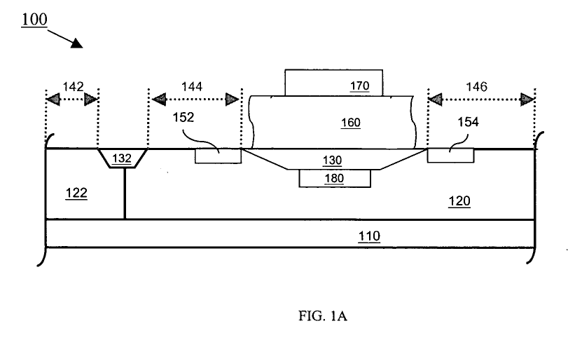

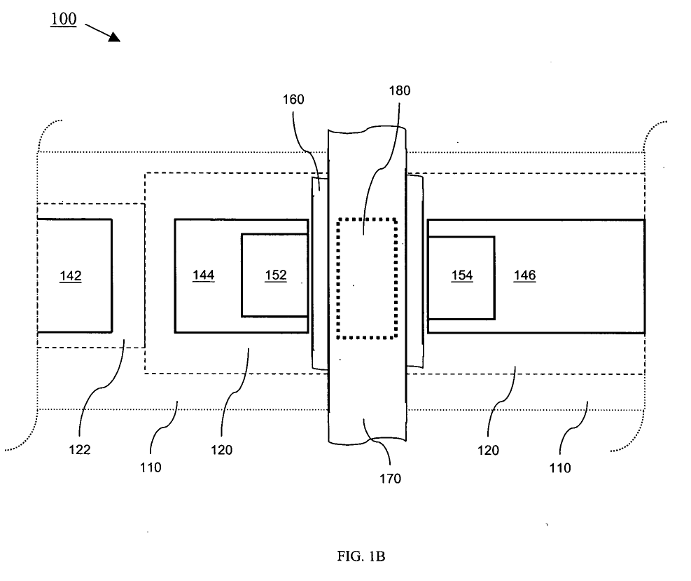

FIGS. 1A and 1B are a sectional view and a plan view of one embodiment of an integrated circuit 100 having a laterally graded well structure, respectively. The integrated circuit 100 includes a semiconductor substrate 110. The substrate may be doped to n-type or p-type. The semiconductor substrate may use silicon, germanium, diamond, silicon carbide, gallium arsenic, SiGe, GaAsP, AlInAs, AlGaAs, GaInP, or a combination thereof.

A p-type well region (“p-well”) 120 is formed in the substrate 110. An n-type well region (“n-well”) 122 may also be formed in the substrate. The p-well 120 and the n-well 122 may contact each other. Both the n-well and p-well regions may be high voltage wells having light dopant concentrations ranging from about 10¹³ atoms/cm² to about 10¹⁶ atoms/cm², for example. The dopants may include phosphorous and arsenic for an n-well, and boron for a p-well. The n-well and p-well may be formed separately by a process such as ion implantation or diffusion. For example, the well regions 120 and 122 may be formed, respectively, by a plurality of processing steps now known or to be developed such as growing a sacrificial oxide on substrate 110, opening a pattern for the location of the n-well region (or p-well region), and implanting n-type dopants (or p-type dopants).

A dielectric isolation feature 130 is formed within the p-well region. Other dielectric isolation features such as feature 132 may also be formed in the substrate 110. The dielectric isolation features 130 and 132 may be formed within the substrate to electrically isolate active regions 142, 144, and 146. The dielectric isolation features may have a structure such as a shallow trench isolation (STI) structure or a local oxidation of silicon (LOCOS) structure.

The active region 144 may further include an n-doped region 152 and the active region 146 may further include an n-doped region 154. Both of the n-doped regions 152 and 154 are within the p-well region 120, are spaced from each other, and are laterally interposed by the dielectric isolation feature 130. The n-type doped regions 152 and 154 may be doped with an n-type impurity such as phosphorous or arsenic. The n-type doped regions may be formed by a process such as ion implantation and/or diffusion. A rapid thermal annealing (RTA) process may be used to activate the implanted dopants after the ion implantation.

The integrated circuit 100 may further include an interlayer dielectric (ILD) feature 160 and a conductive line 170. The ILD feature 160 may be a portion of an ILD layer and interposed between the conductive line 170 and the p-well region 120. The conductive line 170 may cross over or substantially close to the p-well region 120. The conductive line 170 may be designed for a high voltage signal and may be electrically connected to a high voltage transistor such as a double diffused metal-oxide-semiconductor (DMOS).

The ILD feature 160 may comprise silicon dioxide, polyimide, spin-on glass (SOG), fluoride-doped silicate glass (FSG), a low k material, or a combination thereof. The low k material may include Black Diamond® (a product of Applied Materials of Santa Clara, Calif.), Xerogel, Aerogel, amorphous fluorinated carbon, Parylene, BCB, Flare, and SiLK. The ILD feature 160 may be formed by chemical vapor deposition (CVD), atomic layer deposition (ALD), physical vapor deposition (PVD), spin-on coating and/or other processes.

The conductive line 170, as a part of a multilayer interconnect, may comprise aluminum, aluminum alloy, copper, copper alloy, titanium, titanium nitride, tantalum, tantalum nitride, tungsten, polysilicon, metal silicide, or combinations thereof. The conductive line 170 may be formed by processes such as CVD, PVD, and plating.

Further, the integrated circuit 100 includes a p-type doped feature 180 formed in the p-well region 120, interposed between the n-type doped regions 152 and 154, and positioned under the dielectric isolation feature 130. The p-type doped feature 180 may contact the overlying isolation feature 130. The p-type doped feature 180 has a dopant concentration higher than that of the p-well region 120. For example, the p-type doped feature 180 may have a dopant concentration per unit area ranging between about 10¹⁴ atoms/cm² and about 10¹⁸ atoms/cm², while the p-well region may have a dopant concentration per unit area ranging between about 10¹³ atoms/cm² and about 10¹⁶ atoms/cm².

A field isolation may be formed between the two n-type doped regions 152 and 154. A portion of the p-well region 120 may provide a channel between the two n-type doped regions 152 and 154, forming a parasitic field effect transistor. Even though the insulator layer(s), such as the dielectric isolation feature 130, and/or the ILD layer 160, may be relatively thick and may be interposed between the conductive line 170 and the parasitic channel, a signal from the conductive line 170 may have a high enough voltage to activate the parasitic channel and cause field isolation failure. A heavier doping concentration for the field isolation may increase the threshold voltage of the parasitic field effect transistor and enhance the field isolation. A heavy doping concentration may also enhance a well isolation when a p-n junction formed in the interface between the p-well and n-well regions is reverse-biased. However, to minimize or eliminate the breakdown of the integrated circuit 100, a light doped well may be used. To minimize a trade-off between a higher device breakdown voltage using a lighter doping and a higher field isolation threshold voltage and/or better well isolation using a heavier doping, the p-typed doped feature 180 may be used to provide a laterally graded doping profile in the p-well 120 for better field (and well) isolation and higher device breakdown voltage.

In another embodiment, the integrated circuit 100 may have a similar structure but with doping features having reversed dopants. The integrated circuit 100 may be a portion of a microelectronic device having high voltage applications. The microelectronic device may further include a high voltage transistor. The high voltage transistor may be a lateral diffused metal-oxide-semiconductor (LDMOS) transistor formed in a dual-well structure (e.g., a high voltage p-well and a high voltage n-well). The high voltage device may be an LDMOS formed in a triple-well structure (a high voltage n-well, a high voltage p-well, and another high voltage n-well, for example). The high voltage device may be a vertical diffused metal-oxide-semiconductor (VDMOS) or another type of high voltage transistor. In some examples, the conductive line 170 may be close to the p-well region. The field isolation may be reinforced by the low voltage p-type doped region 180 and still be effective with the existence of a high voltage conductive line near the p-well region 120.

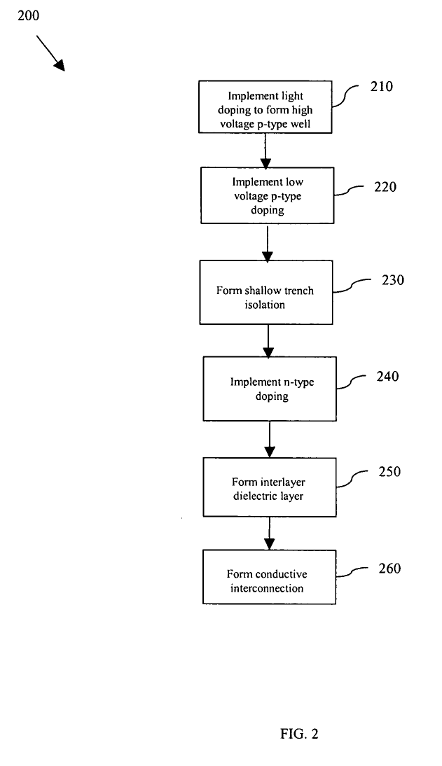

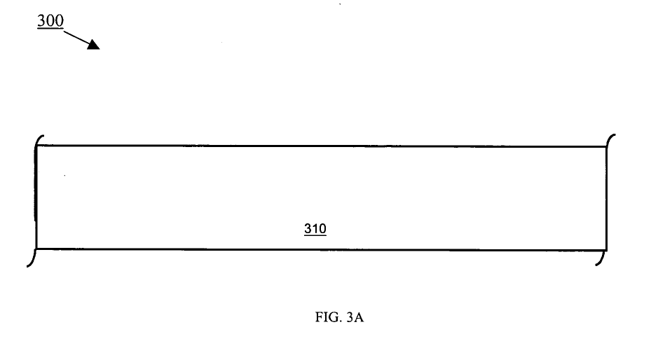

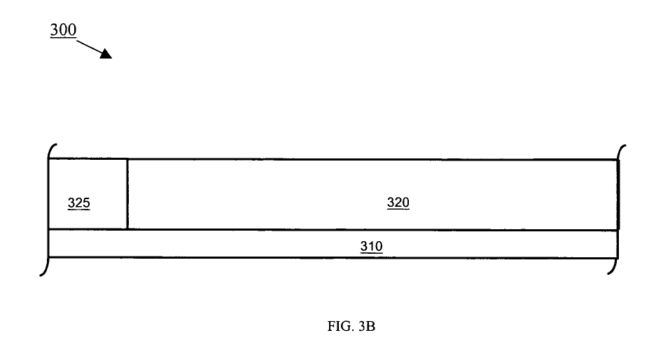

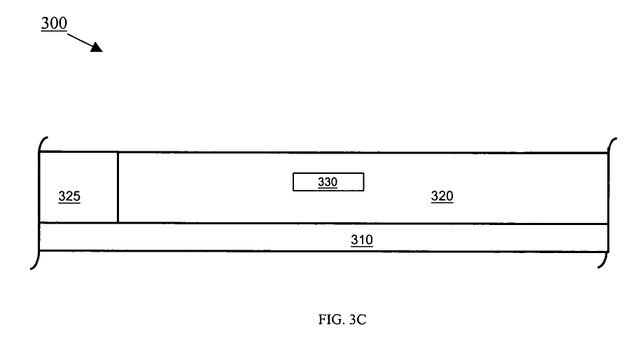

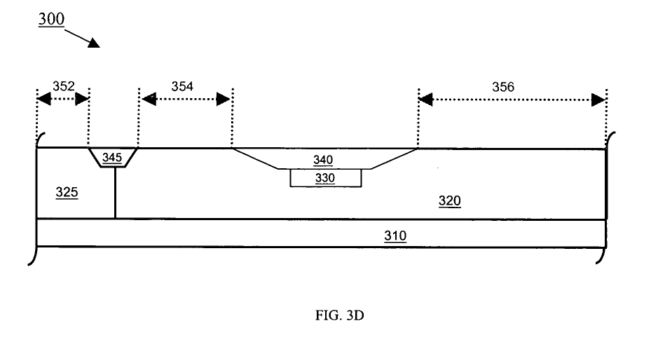

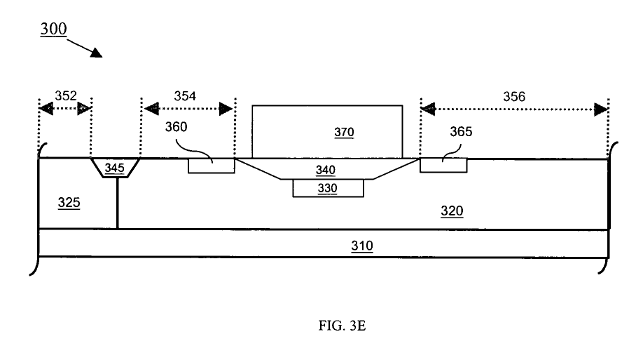

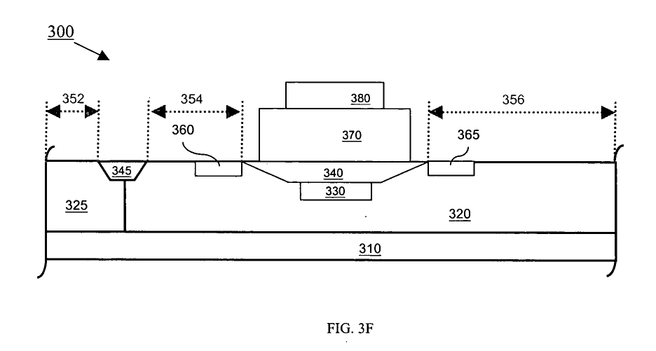

Referring to FIG. 2 and with additional reference to FIGS. 3A-3F, in another embodiment, a method 200 may be used to fabricate a laterally graded well structure 300 (e.g., such as that described with respect to the integrated circuit 100 of FIG. 1). FIGS. 3A-3F provide sectional views of one embodiment of the laterally graded well structure 300 in intermediate stages of manufacturing.

The structure 300 includes a semiconductor substrate 310, as shown in FIG. 3A, that may comprise silicon. Other options for the semiconductor substrate 310 may include germanium, diamond, silicon carbide, gallium arsenic, SiGe, GaAsP, AlInAs, AlGaAs, GaInP, or a combination thereof. The substrate 310 may be further doped either as n-type or p-type.

In step 210 of FIG. 2 and with additional reference to FIG. 3B, p-type dopants may be introduced to the substrate 310 to form a p-type high voltage well region (“HVPW”) 320. N-type dopants may be introduced to the substrate 310 to form an n-type high voltage well (“HVNW”) 325. The dopants may be introduced by various processes such as ion implantation and/or diffusion. The doping may further include forming a doping mask by a thin film deposition process, patterning the doping mask using conventional photolithography, and removing the doping mask. A post annealing process may also be followed if ion implantation processing is used. Dopants for the HVNW 325 may include phosphorous and arsenic. Dopants for the HVPW 320 may include boron. It is understood that the FIG. 3B only shows a portion of each well for simplicity. An exemplary doping dose for both the n-well and p-well regions may range from about 10¹³ atoms/cm² to about 10¹⁶ atoms/cm².

In step 220 and with additional reference to FIG. 3C, a low voltage p-type doped region 330 may be formed by processing steps similar to the doping described in step 210. However, the doping dose to form the low voltage doped region 330 may be lighter than that used in the p-well region 320. For example, the p-type doped feature 330 may be formed using a doping dose ranging between about 10¹⁴ atoms/cm² and about 10¹⁸ atoms/cm². Alternatively, the low voltage p-type doped region 330 may be formed with other low voltage p-type doped areas in a single processing sequence.

In step 230 and with additional reference to FIG. 3D, an isolation structure 340 may be formed over the low voltage p-type doped region 330. Other isolation structures such as a structure 345 may also be formed. The isolation structures, including 340 and 345, may be formed utilizing isolation technology such as LOCOS and/or STI. LOCOS may include thermal oxidation using a patterned mask layer. STI may include dry etching a trench in the substrate and filling the trench with insulator materials such as silicon oxide, silicon nitride, or silicon oxynitride. The trench may have a multi-layer structure including silicon oxide and silicon nitride. In one embodiment, the STI structure may be created using a process sequence such as: growing a pad oxide, forming a low pressure chemical vapor deposition (LPCVD) nitride layer, patterning an STI opening using photoresist and masking, etching a trench in the substrate, growing a thermal oxide trench liner to improve the trench interface, filling the trench with CVD silicon oxide or silicon nitride, using chemical mechanical planarization (CMP) to etch back, and using nitride stripping to remove the nitride mask.

The isolation structures 340 and 345 define active regions 352, 354, and 356. In one example, the active region 352 is formed within the n-well region 325. The active regions 354 and 356 are formed within the p-well region 320.

Alternatively, the sequence of forming the low voltage p-type doped region 330 (step 220) and forming the isolation structure 340 (step 230) may be changed. For example, the isolation structure 340 may be formed and then the low voltage p-type doping 330 may be implemented. It is understood that other changes may be made to the sequence, such as forming the isolation structure 340 prior to forming the high voltage well region 320 (step 210).

In step 240 and with additional reference to FIG. 3E, two n-type doped regions 360 and 365 may be formed by an ion implantation process, wherein the ion implantation processing may be similar to that of the ion implantation processing of steps 210 and 220. Dopants may include phosphorous and arsenic.

In step 250, an ILD layer 370 may be further formed on the substrate over the p-well region 320. The ILD layer 370 may comprise silicon dioxide, polyimide, spin-on glass (SOG), fluoride-doped silicate glass (FSG), low k materials, and a combination thereof. The ILD layer may be formed by CVD, atomic layer deposition (ALD), physical vapor deposition (PVD), spin-on coating, and/or other processes. The ILD layer 370 may be horizontally and vertically extended to isolate various conductive features.

In step 260 and with additional reference to FIG. 3F, a conductive feature 380 may be formed on the substrate. The conductive feature 380 may be separated from the low voltage p-type doped region 330 by isolation structures such as the isolation structure 340 and the ILD layer 370. The conductive feature 380 may comprise aluminum, aluminum/copper alloy, copper, titanium, titanium nitride, tantalum, tantalum nitride, tungsten, polysilicon, metal silicide, or combinations thereof. The conductive feature 380 may be formed by CVD, PVD, plating, ALD, other deposition methods, or combinations thereof.

The method 200 and the laterally graded well structure 300 illustrated here are only examples of a laterally graded well structure and a method to manufacture the same. It is understood that the method may be extended and changed without departing from the spirit and scope of the present disclosure. For example, the method may further include other intermediate processing steps. For example, if n-type doped regions 360 and 365 are designed to be electrically connected, a metal silicide may be formed on both surfaces of the n-type doped regions using manufacturing processes known in the art. Furthermore, some illustrated steps may be divided into additional steps and/or may be combined.

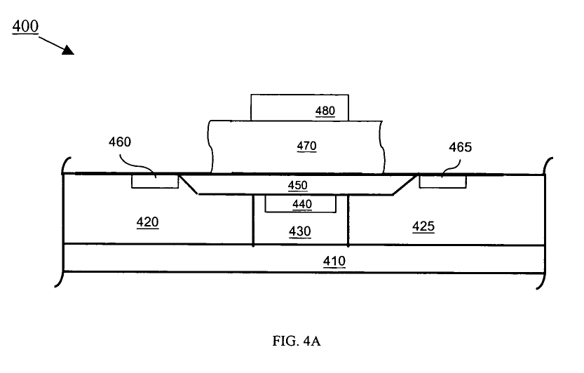

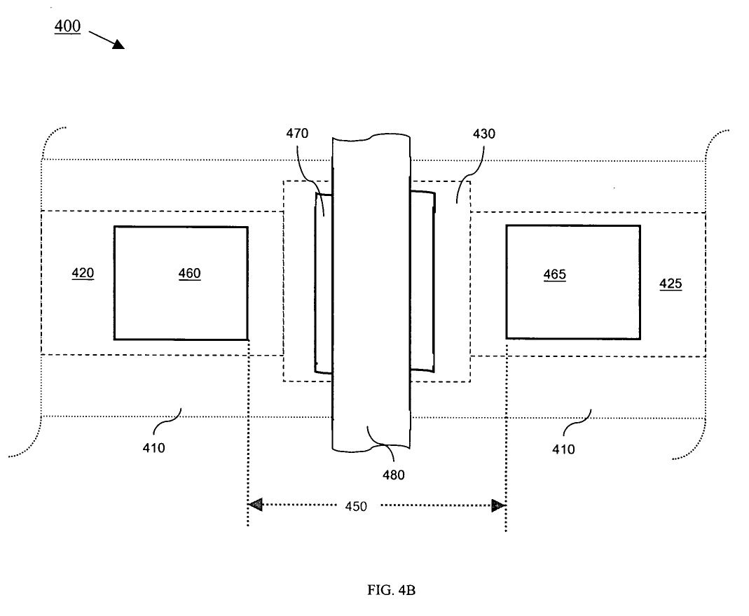

Referring to FIG. 4A and FIG. 4B, illustrated are a sectional view and a plan view of another embodiment of an integrated circuit 400 having a laterally graded well structure. The integrated circuit 400 may include a semiconductor substrate 410. The substrate 410 may be substantially similar to the substrate 110 of FIG. 1A and FIG. 1B. For example, the substrate 410 may comprise silicon and/or other semiconductor materials. The substrate 410 may be doped to n-type or p-type.

N-type well regions (“n-well” or “HVNW”) 420 and 425 may be formed in the substrate 410. A p-type well region (“p-well” or “HVPW”) 430 may also be formed in the substrate 410 between and in contact with the two n-wells 420 and 425. The n-well and p-well regions may have light dopant concentrations per unit area ranging from about 10¹³ atoms/cm² to about 10¹⁶ atoms/cm². The dopants may include phosphorous and arsenic for the n-type regions, and boron for the p-type region. The n-wells and p-well may be formed separately by a process such as ion implantation.

The integrated circuit 400 may further comprise a low voltage p-type doped region 440 formed in the p-well 430 and may have a dopant concentration higher than that of the p-well 430. In one embodiment, the p-type doped feature 440 may have a dopant concentration per unit area ranging between about 10¹⁴ atoms/cm² and about 10¹⁸ atoms/cm². The doped region 440 is positioned under dielectric isolation features (described below).

A dielectric isolation feature 450 is formed in the substrate 410. The dielectric isolation feature 450 may be overlying the p-type doped region 440 and comprise a STI or a LOCOS structure.

An n-type doped region 460 is formed within the n-well 420 and another n-type doped region 465 is formed within the n-well 425. The two n-type doped regions 460 and 465 are spaced from each other, and are laterally interposed by the p-well 430 having the p-type doped region 440. The n-type doped regions 460 and 465 may be doped with an n-type impurity such as phosphorous or arsenic and may be formed by ion implantation and/or diffusion. Other processes may include patterning a doped region and using a rapid thermal annealing (RTA) step to activate the implanted dopants if ion implantation is used.

The integrated circuit 400 further includes an interlayer dielectric (ILD) feature 470 and a conductive line 480. The ILD feature 470 may be a portion of an ILD structure and may be interposed between the conductive line 480 and the p-well doped region 440. The conductive line 480 may be substantially over or at least substantially close to the dielectric isolation feature 450. The conductive line 480 may be designed for high voltage signals.

A field isolation may be formed between the two n-type doped regions 460 and 465. The p-well region 430 may provide a channel between the two n-type doped regions 460 and 465, forming a parasitic field effect transistor. Even though the insulator layer(s), such as the dielectric isolation feature 130, and/or the ILD layer 160, may be relatively thick, a high voltage signal from the conductive line 480 may have a high enough voltage to activate the parasitic channel and cause field isolation failure. A heavier doping concentration for the field isolation may increase the threshold voltage of the parasitic field effect transistor and enhance the field isolation. A heavy doping concentration may also enhance a well isolation when a p-n junction formed in the interface between the p-well and n-well regions is reverse-biased. However, to minimize or eliminate the breakdown of the integrated circuit 400, a light doped well may be used. To minimize a trade-off between a higher device breakdown voltage using a lighter doping and a higher field isolation threshold voltage and/or better well isolation using a heavier doping, the p-typed doped feature 440 may be used to provide a laterally graded doping profile in the p-well 430 for better field (and well) isolation and higher device breakdown voltage.

The structures and features illustrated above including the substrate, the well regions, the doped regions, the isolation structures (including STI, LOCOS, and ILD), and the conductive line may be substantially similar to those equivalent features of the integrated circuit 100 of FIG. 1 in terms of materials and manufacturing processes. In another embodiment, the integrated circuit 400 may have a similar structure as that described, but each doping feature may have a reversed doping type. The device 400 may be a portion of a microelectronic device having various high voltage applications. The device 400 may further include a high voltage transistor. The high voltage transistor may comprise a double diffused MOD (DMOS) such as a LDMOS or a VDMOS.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

1. A device having a semiconductor substrate comprising:
a well region located in the semiconductor substrate and comprising a first-type dopant;
first and second doped regions located in the well region and comprising a second-type dopant, the first and second doped regions being separated from each other by a dielectric isolation feature; and
a third doped region located in and in contact with the well region under the dielectric isolation feature and between the first and second doped regions, wherein the third doped region comprises the first-type dopant and has a dopant concentration higher than that of the well region.

2. The device of claim 1 further comprising an additional well region located in the semiconductor substrate, wherein the additional well region comprises the second-type dopant and contacts the well region.

3. The device of claim 2 wherein the well region and the additional well region have dopant concentrations ranging between about 10¹³ atoms/cm² and about 10¹⁶ atoms/cm².

4. The device of claim 2 wherein the third doped region has a dopant concentration ranging between about 10¹⁴ atoms/cm² and about 10¹⁸ atoms/cm².

5. The device of claim 1 further comprising a conductive line overlying the semiconductor substrate and substantially close to the well region.

6. The device of claim 5 wherein the conductive line is for a high voltage signal.

7. The device of claim 1 wherein the first-type dopant is one of an n-type dopant and a p-type dopant, and wherein the second-type dopant is the other of the n-type and p-type dopants.

8. The device of claim 7 wherein the n-type dopant comprises phosphorous.

9. The device of claim 7 wherein the n-type dopant comprises arsenic.

10. The device of claim 7 wherein the p-type dopant comprises boron.

11. The device of claim 1 wherein the first-type and second-type dopants are implemented by ion implantation.

12. The device of claim 1 further comprising at least one high voltage transistor.

13. The device of claim 12 wherein the high voltage transistor comprises a lateral diffused metal-oxide-semiconductor (LDMOS) transistor.

14. The device of claim 12 wherein the high voltage transistor comprises a vertical diffused metal-oxide-semiconductor (VDMOS) transistor.

15. The device of claim 1 wherein the dielectric isolation feature comprises a shallow trench isolation (STI) structure.

16. The device of claim 1 wherein the dielectric isolation feature comprises local oxidation of silicon (LOCOS).

17. The device of claim 1 wherein the dielectric isolation feature comprises an interlayer dielectric (ILD) layer.

18. The device of claim 1 wherein the third doped region contacts the dielectric isolation feature.

19. A device having a semiconductor substrate comprising:
first and second well regions formed in the semiconductor substrate and in contact with each other, wherein the first well region comprises a first-type dopant and the second well region comprises a second-type dopant;
first and second doped regions formed in the first well region and comprising the second-type dopant, wherein the first and second doped regions are separated from each other by a dielectric isolation feature; and
a third doped region formed within and contacting the first well region using the first-type dopant and positioned proximate to the dielectric isolation feature and between the first and second doped regions, wherein the third doped region has a dopant concentration higher than that of the first well region.

20. A method to form a laterally graded well structure in a semiconductor substrate comprising:
using a first-type dopant to form a first high voltage well in the semiconductor substrate;
using the first type-dopant to form a low voltage doped region in contact with the first high voltage well, wherein the low voltage doped region has a dopant concentration higher that that of the first high voltage well;
forming a dielectric isolation feature over the low voltage doped region; and
using a second-type dopant to form first and second doped regions positioned on both sides of the low voltage doped region in the first high voltage well.

21. The method of claim 20 further comprising using the second-type dopant to form a second high voltage well in the semiconductor substrate, wherein the second high voltage well contacts the first high voltage well.

22. The method of claim 20 further comprising:
forming an interlayer dielectric (ILD) film over the semiconductor substrate; and
forming a metal line crossing over the ILD film wherein the metal line is designed for high voltage signals.

23. The method of claim 20 wherein the dielectric isolation feature comprises shallow trench isolation (STI).

24. The method of claim 20 wherein using the first-type dopant to form the first high voltage well includes using a dopant concentration ranging between about 10¹³ atoms/cm² and about 10¹⁶ atoms/cm².

25. The method of claim 20 wherein using the first-type dopant to form the low voltage doped region includes using a dopant dose ranging between about 10¹⁴ atoms/cm² and about 10¹⁸ atoms/cm².

26. The method of claim 20 wherein the low voltage doped region is formed along with other low voltage doped features in a single processing sequence.

27. The method of claim 20 wherein the dielectric isolation feature is formed before forming the low voltage doped region.

28. The method of claim 20 wherein all doping occurs by ion implantation.

29. The method of claim 20 wherein the first-type dopant is one of an n-type dopant and a p-type dopant, and wherein the second-type dopant is the other.

30. The method of claim 29 wherein the n-type dopant comprises phosphorous, arsenic, or a combination thereof.

31. The method of claim 29 wherein the p-type dopant comprises boron.

32. A device having a semiconductor substrate comprising:
first, second, and third well regions formed in the semiconductor substrate, wherein the first and third well regions comprise a first-type dopant, the second well region comprises a second-type dopant, and the second well region is positioned between and in contact with the first and third well regions;
first and second doped regions formed in the first and third well regions, respectively, wherein the first and second doped regions comprise the first-type dopant and are separated by a dielectric isolation feature; and
a third doped region formed in the second well region and positioned under the dielectric isolation feature, wherein the third doped region comprises the second-type dopant and has a dopant concentration higher than that of the second well region.

33. The device of claim 32 further comprising a conductive line overlying the semiconductor substrate.

34. The device of claim 32 further comprising at least one high voltage transistor.

35. The device of claim 32 wherein the isolation features comprises a shallow trench isolation (STI) structure.

36. The device of claim 32 wherein the second well region has a dopant concentration per unit area ranging between about 10¹³ atoms/cm² and about 10¹⁶ atoms/cm².

37. The device of claim 36 wherein the third doped region has a dopant concentration per unit area ranging between about 10¹⁴ atoms/cm² and about 10¹⁸ atoms/cm².
